(19) United States
(12) Patent Application Publication
(10) Pub. No.: US 2023/0420422 A1
(43) Pub. Date: Dec. 28, 2023

(54) LED PACKAGE DEVICE AND PREPARATION METHOD THEREOF, AND DISPLAY DEVICE

(71) Applicant: FOSHAN NATIONSTAR OPTOELECTRONICS CO., LTD., Foshan (CN)

(72) Inventors: Liang NI, Foshan (CN); Jinhui ZHANG, Foshan (CN); Lifang LIANG, Foshan (GD); Pingxia LIANG, Foshan (CN); Long ZHAO, Foshan (CN); Danwei LI, Foshan (CN)

(73) Assignee: FOSHAN NATIONSTAR OPTOELECTRONICS CO., LTD., Foshan, GD (CN)

(21) Appl. No.: 18/212,743

(22) Filed: Jun. 22, 2023

(30) Foreign Application Priority Data
Jun. 23, 2022 (CN) 202210732112.0

(51) Int. Cl. H01L 25/075; H01L 33/62; H01L 33/44; H01L 33/00; H01L 33/56

(52) U.S. Cl. CPC H01L 25/0753; H01L 33/62; H01L 33/44; H01L 33/0093; H01L 33/56; H01L 2933/0025; H01L 2933/0066; H01L 2933/0016; H01L 2933/005

(57) ABSTRACT

Provided are an LED package device and a preparation method thereof, and a display device. The package device includes a transparent substrate, a black layer, a transparent bonding layer, multiple LED chips, and a mold protective layer. The multiple LED chips are fixed to the transparent substrate based on the transparent bonding layer. The black layer is configured to cover the transparent bonding layer. The black layer is provided with multiple matching holes. The multiple LED chips are matched in the multiple matching holes in a one-to-one correspondence. The cover area of the transparent bonding layer is S1. The area of the top surface of the transparent substrate is S2. The constraint relationship between S1 and S2 is S1<S2. The mold protective layer is configured to wrap the black layer, the transparent bonding layer, and the multiple LED chips on the transparent substrate.

### CROSS-REFERENCE TO RELATED APPLICATION(S)

This application claims priority to Chinese Patent Application No. 202210732112.0 filed Jun. 23, 2022, the disclosure of which is incorporated herein by reference in its entirety.

### TECHNICAL FIELD

The present disclosure relates to the field of light-emitting diode (LED) technology and, in particular, to an LED package device and a preparation method thereof, and a display device.

### BACKGROUND

In an LED display screen, an LED chip plays the role of light-emitting and display. In the current LED chip technology, an LED chip is manufactured by means of size reduction. Self-light-emitting micron-level LEDs are used as light-emitting pixel units and assembled to a drive panel to form high-density LED array display. LED chips have characteristics of small size, high integration level, and self-light-emitting and have greater advantages in brightness, resolution, contrast, energy consumption, service life, response speed, and thermal stability.

However, since the size of LED chips is small, there are many technical difficulties to be overcome in transfer and test sorting. Currently, multiple LED chips are packaged as a single light-emitting device for test sorting. However, since the size of chips is small, the light intensity is insufficient, and the light-emitting brightness is insufficient. Moreover, it is difficult to transfer the LED chips in the packaging process. The air tightness of a package device is insufficient, resulting in that the package device is easily invaded by water vapor, thereby reducing the service life of the device.

### SUMMARY

The object of the present disclosure is to overcome deficiencies in the related art. The present disclosure provides an LED package device and a preparation method thereof, and a display device. According to the LED package device, the brightness of the LED package device is improved by providing a black layer with matching holes. By combining a mold protective layer and a transparent substrate, the air tightness of the device is improved, and the service life of the device is prolonged.

The present disclosure provides an LED package device. The package device includes a transparent substrate, a black layer, a transparent bonding layer, a plurality of LED chips, and a mold protective layer. The plurality of LED chips are fixed to the transparent substrate based on the transparent bonding layer.

The black layer is configured to cover the transparent bonding layer. The black layer is provided with a plurality of matching holes. The plurality of LED chips are matched in the plurality of matching holes in a one-to-one correspondence.

The cover area of the transparent bonding layer is S1. The area of the top surface of the transparent substrate is S2. The constraint relationship between S1 and S2 is S1<S2.

The mold protective layer is configured to wrap the black layer, the transparent bonding layer, and the plurality of LED chips on the transparent substrate.

In an embodiment, the transparent bonding layer is located in the top surface of the transparent substrate, and the outer contour edge of the transparent bonding layer is not in contact with a side of the transparent substrate.

In an embodiment, the package device further includes a planar layer, where the planar layer is configured to cover a surface of the black layer, and the top surface of the planar layer is flush with top surfaces of the plurality of LED chips.

In an embodiment, the package device further includes a wiring layer and device electrodes, where the wiring layer is disposed on the planar layer and electrically connected to top electrodes of the plurality of LED chips; and the device electrodes are located on the wiring layer and connected to the wiring layer.

In an embodiment, the transparent bonding layer is made of an acrylic film, an epoxy resin film, a silicone resin film, a silica gel film, or an ultra-violet (UV) film.

In an embodiment, the black layer is made of black photoresist, or the black layer is a titanium aluminum nitride thin film.

In an embodiment, the thickness of the black layer is h1, and a value range of h1 is h1≤1 μm.

In an embodiment, the planar layer is an insulation material.

In an embodiment, the device electrodes include a plurality of sub-electrodes, and the plurality of sub-electrodes include at least one common electrode; and cathode ends of the plurality of LED chips are connected to the at least one common electrode, or anode ends of the plurality of LED chips are connected to the at least one common electrode.

The present disclosure further provides a preparation method of an LED package device. The method is applied to the preparation of the LED package device. The preparation method includes the following steps: the plurality of LED chips are bonded to a temporary carrier plate; the transparent bonding layer is covered on the transparent substrate, and the black layer with the plurality of matching holes is formed on the transparent bonding layer; the transparent bonding layer and the black layer are patterned to expose part of the top surface of the transparent substrate; the plurality of LED chips on the temporary carrier plate are transferred to the plurality of matching holes in the one-to-one correspondence so that the plurality of LED chips are bonded to the transparent bonding layer exposed in the plurality of matching holes; a planar layer, a wiring layer, and device electrodes are successively formed on the black layer; and the mold protective layer is formed on the transparent substrate to complete the preparation of the LED package device.

In an embodiment, the step in which the plurality of LED chips are bonded to the temporary carrier plate includes that an adhesive film is attached on a temporary substrate to form the temporary carrier plate, and the plurality of LED chips with a substrate are attached on the temporary carrier plate; and the substrate is lifted off through laser etching technology to obtain the temporary carrier plate to which the plurality of LED chips are bonded.

In an embodiment, the temporary substrate is made of glass, sapphire, or silicon.

In an embodiment, the adhesive film is a polydimethylsiloxane (PDMS) film or a UV film.

In an embodiment, the step in which the transparent bonding layer is covered on the transparent substrate includes that the transparent bonding layer is formed on the transparent substrate through a spin-coating method, or the transparent bonding layer is formed through a vacuum attaching method.

In an embodiment, the step in which the black layer with the plurality of matching holes is formed on the transparent bonding layer includes that black photoresist is spin-coated on the transparent bonding layer to form a black adhesive layer; the black adhesive layer is exposed to form a pattern layer with hole-shaped light spots; and the hole-shaped light spots on the pattern layer are dissolved through a development process to form the black layer with the plurality of matching holes.

In an embodiment, the patterning is laser etching or chemical etching.

In an embodiment, the step in which the plurality of LED chips on the temporary carrier plate are transferred to the plurality of matching holes in the one-to-one correspondence so that the plurality of LED chips are bonded to the transparent bonding layer exposed in the plurality of matching holes includes that the plurality of LED chips are bonded to the plurality of matching holes according to the order of heights of the plurality of LED chips from low to high in the one-to-one correspondence.

In an embodiment, the step in which the planar layer is formed on the black layer includes that the planar layer is processed through photolithography to enable the edge of the planar layer to be flush with the black layer; and opening portions are formed at corresponding positions of the plurality of LED chips through a photolithography process.

In an embodiment, the step in which the wiring layer and the device electrodes are successively formed on the black layer includes that the wiring layer is prepared above the planar layer through evaporation; and the device electrodes are prepared on the wiring layer through an electroplating process or through an electroless plating process.

In an embodiment, the step in which the mold protective layer is formed on the transparent substrate includes that an epoxy resin is poured on the transparent substrate for molding to form the mold protective layer, and the device electrodes are exposed on the top of the mold protective layer through grinding and polishing processes.

The present disclosure further provides a display device. The display device includes a carrier plate and a plurality of display modules arrayed on the carrier plate. A display module includes a circuit board. The circuit board is provided with a plurality of LED package devices.

The present disclosure provides an LED package device and a preparation method thereof, and a display device. A plurality of LED chips are packaged on the LED package device to facilitate testing and sorting of the LED chips. By providing a black layer with matching holes, the light intensity of the LED chips is improved, and the brightness of the LED package device is improved. In the preparation method, LED chips are transferred through a temporary carrier plate in the preparation process so that the preparation efficiency is improved. By the design of the spacing between LED chips on the LED package device, the device preparation safety is improved. The mold protective layer and the transparent substrate are directly contacted and bonded through a patterning process. The mold protective layer completely wraps the black layer and the transparent bonding layer, thereby avoiding the black layer and the transparent bonding layer from directly contacting the external environment, prolonging the path of water vapor entering the LED device, improving the structure stability of the LED package device, and prolonging the service life of the device.

### BRIEF DESCRIPTION OF DRAWINGS

To illustrate the technical solutions in embodiments of the present disclosure or the related art more clearly, the drawings used in the description of the embodiments or the related art are briefly described below. Apparently, the drawings described below illustrate only part of the embodiments of the present disclosure, and those of ordinary skill in the art may obtain other drawings based on the drawings described below on the premise that no creative work is done.

FIG. 1 is a diagram illustrating the structure of an LED package device according to an embodiment of the present disclosure.

FIG. 2 is a top view illustrating the structure of an LED package device according to an embodiment of the present disclosure.

FIG. 3 is a diagram illustrating the structure of a display device according to an embodiment of the present disclosure.

FIG. 4 is a flowchart of a preparation method of an LED package device according to an embodiment of the present disclosure.

FIG. 5 is a diagram illustrating the preparation of a temporary carrier plate according to an embodiment of the present disclosure.

FIG. 6 is a diagram illustrating the structure of a temporary carrier plate according to an embodiment of the present disclosure.

FIG. 7 is a diagram illustrating the preparation of a black layer and a transparent bonding layer according to an embodiment of the present disclosure.

FIG. 8 is a top diagram illustrating the structure of a black layer and the structure of a transparent bonding layer according to an embodiment of the present disclosure.

FIG. 9 is a sectional view illustrating the structure of a sub-unit according to an embodiment of the present disclosure.

FIG. 10 is a diagram illustrating the bonding structure of a temporary carrier plate and a transparent substrate according to an embodiment of the present disclosure.

FIG. 11 is a diagram illustrating the transfer state of LED chips according to an embodiment of the present disclosure.

FIG. 12 is a diagram illustrating the preparation of a planar layer, a wiring layer, and device electrodes according to an embodiment of the present disclosure.

### DETAILED DESCRIPTION

The technical solutions in the embodiments of the present disclosure are described clearly and completely in conjunction with the drawings in the embodiments of the present disclosure. Apparently, the embodiments described are part, not all, of the embodiments of the present disclosure. Based on the embodiments of the present disclosure, all other embodiments obtained by those of ordinary skill in the art are within the scope of the present disclosure on the premise that no creative work is done.

Embodiment of an LED Package Device

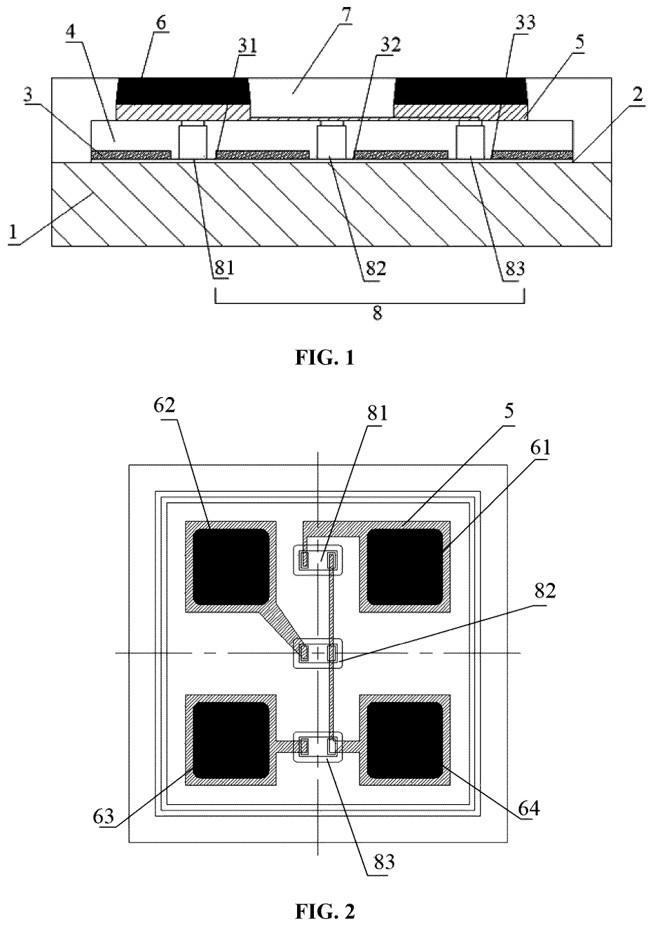

Referring to FIG. 1 and FIG. 2, an LED package device 10 includes a transparent substrate 1, a planar layer 4, a black layer 3, a wiring layer 5, a transparent bonding layer 2, and multiple LED chips 8. The multiple LED chips 8 are fixed to the transparent substrate 1 based on the transparent bonding layer 2.

Further, the multiple LED chips 8 include at least three LED chips of different colors to meet light-emitting requirements of the LED package device 10. In this embodiment, the multiple LED chips 8 include a first chip 81, a second chip 82, and a third chip 83. The first chip 81 is a red chip. The second chip 82 is a green chip. The third chip 83 is a blue chip.

Specifically, the black layer 3 covers the transparent bonding layer 2. The black layer 3 is provided with multiple matching holes. The multiple matching holes include a first matching hole 31, a second matching hole 32, and a third matching hole 33. The multiple LED chips 8 are matched in the multiple matching holes in a one-to-one correspondence. The multiple matching holes enable the LED chips 8 to be directly bonded on the transparent bonding layer 2 to avoid shielding the LED chips 8, thereby ensuring that the LED chips 8 can emit light normally.

Further, the black layer 3 is made of black photoresist. Alternatively, the black layer 3 may be a TiAlN thin film (titanium aluminum nitride thin film) to improve the light intensity of the LED package device 10.

Further, the thickness of the black layer 3 is h1. The value range of h1 is h1≤1 μm, facilitating the processing of the matching holes. The thickness of the black layer 3 cannot exceed the thickness of the LED chip. Otherwise, the LED chip cannot be bonded to the transparent bonding layer 2.

Specifically, the cover area of the transparent bonding layer 2 is S1. The area of the top surface of the transparent substrate 1 is S2. The constraint relationship between S1 and S2 is S1<S2. The position around the top surface of the transparent substrate 1 may be bonded to a mold protective layer 7. Thus, the air tightness and structure reliability of the package device are improved.

Further, the transparent bonding layer 2 is located in the top surface of the transparent substrate 1. The outer contour edge of the transparent bonding layer 2 is not in contact with sides of the transparent substrate 1.

Further, the transparent bonding layer 2 is made of an acrylic film, an epoxy resin film, a silicone resin film, a silica gel film, or a UV film. The bonding performance of the transparent bonding layer 2 and the LED chips is good. The LED chips can be firmly bonded to the transparent bonding layer 2.

Specifically, the planar layer 4 covers the surface of the black layer 3. The planar layer 4 is an insulation material to fix the LED chips, improve the structure stability of the LED package device 10, and provide a planar top surface, thereby facilitating the laying of the wiring layer 5.

Further, the planar layer 4 may be a low-temperature-cured polymer photolithographic material such as a photosensitive polyimide. After the planar layer 4 is cured and formed, it is convenient to perform a photolithographic pattern process. The edge of the planar layer 4 is flush with the black layer 3. The top surface of the planar layer 4 is flush with the top surfaces of the LED chips 8 to expose top electrodes of the LED chips 8, thereby facilitating the contact and connection between the top electrodes and the wiring layer 5.

Specifically, the wiring layer 5 is disposed on the planar layer 4. The wiring layer 5 is electrically connected to top electrodes of the multiple LED chips 8. Device electrodes 6 are disposed on the wiring layer 5. The device electrodes 6 are connected to the top electrodes of the multiple LED chips 8 based on the wiring layer 5.

Further, the device electrodes 6 are made of metal. The metal may be one of commonly used metals such as gold, tin, or copper.

Specifically, the device electrodes 6 include a first sub-electrode 61, a second sub-electrode 62, a third sub-electrode 63, and a fourth sub-electrode 64. The fourth sub-electrode 64 is a common electrode. The LED package device 10 has a common electrode structure, thereby simplifying the external electrode structure of the device and facilitating access to an external circuit.

Further, the device may have a common cathode structure. The first sub-electrode 61 is connected to the anode of the first chip 81. The second sub-electrode 62 is connected to the anode end of the second chip 82. The third sub-electrode 63 is connected to the anode end of the third chip 83. The fourth sub-electrode 64 is connected to cathode ends of the first chip 81, the second chip 82, and the third chip 83.

Further, the device may have a common anode structure. The first sub-electrode 61 is connected to the cathode of the first chip 81. The second sub-electrode 62 is connected to the cathode end of the second chip 82. The third sub-electrode 63 is connected to the cathode end of the third chip 83. The fourth sub-electrode 64 is connected to anode ends of the first chip 81, the second chip 82, and the third chip 83.

Specifically, by combining the mold protective layer 7 with the transparent substrate 1, the structure stability and reliability of the LED package device 10 can be improved. The planar layer 4, the black layer 3, the wiring layer 5, the transparent bonding layer 2, and the multiple LED chips 8 are wrapped in the mold protective layer 7. Thus, the path of water vapor entering the LED package device 10 can be prolonged, the risk of damage to the device can be reduced, and the service life of the device can be effectively prolonged.

Further, top surfaces of the device electrodes 6 may be flush with the top surface of the mold protective layer 7. Alternatively, top surfaces of the device electrodes 6 may be higher than the top surface of the mold protective layer 7 to ensure that the device electrodes 6 can be exposed on the top of the mold protective layer 7. The LED package device 10 may access an external circuit based on the device electrodes 6.

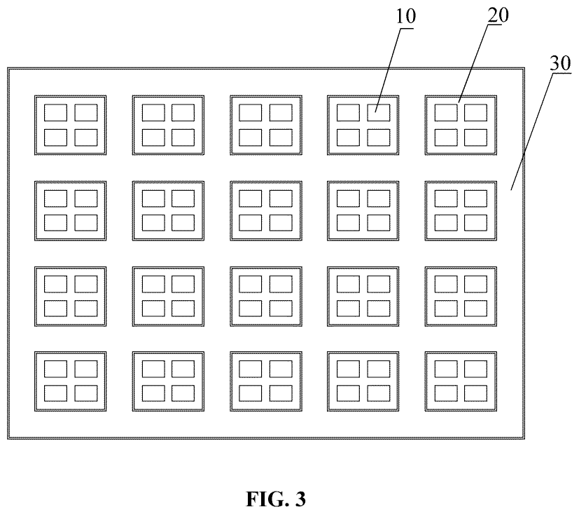

Referring to FIG. 3, an embodiment of the present disclosure further provides a display device. The display device includes a carrier plate 30 and multiple display modules arrayed on the carrier plate. The display module includes a circuit board 20. The circuit board 20 is provided with multiple LED package devices 10.

Further, any one of LED package devices 10 on a circuit board 20 may be separately driven to light up. The display effect of different images on the carrier plate 30 can be completed by cooperation of the multiple display modules on the carrier plate 30.

The embodiment of the present disclosure provides an LED package device and a display device. Multiple LED chips are packaged on the LED package device to facilitate testing and sorting of the LED chips. By providing the black layer 3 with matching holes, the light intensity of the LED chips is improved, and the brightness of the LED package device is improved. The mold protective layer 7 and the transparent substrate 1 are combined so that the mold protective layer 7 is well combined with the transparent substrate 1 and other components. Thus, the structure stability and the air tightness of the LED device are improved, and the black layer 3 and the transparent bonding layer 2 are prevented from being directly exposed to the external environment. Moreover, the path of water vapor invading the device is prolonged, the risk of water vapor invading is reduced, and the service life of the device is prolonged.

Embodiment of a preparation method of an LED package device

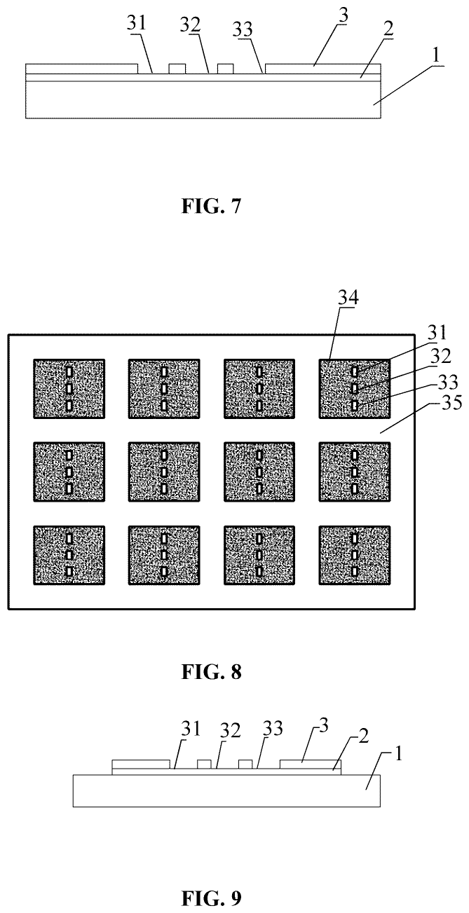

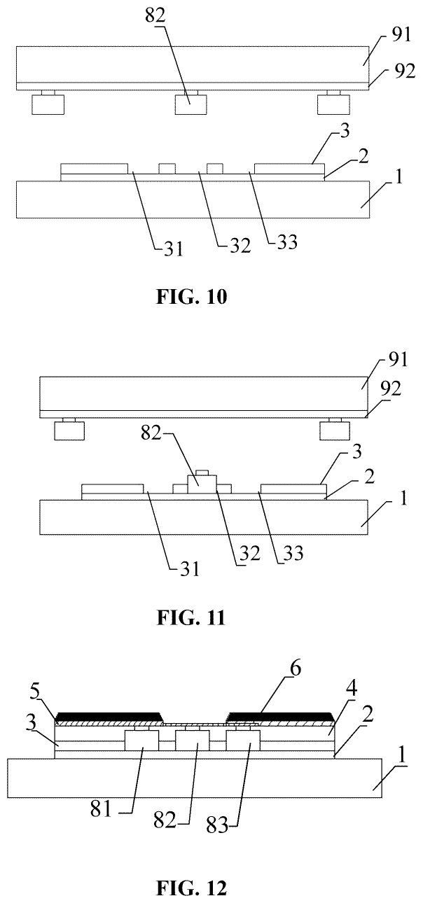

Referring to FIGS. 4 to 12, the preparation method of an LED package device includes the steps S11 to S16 described below.

In S11, multiple LED chips 8 are bonded to a temporary carrier plate 9.

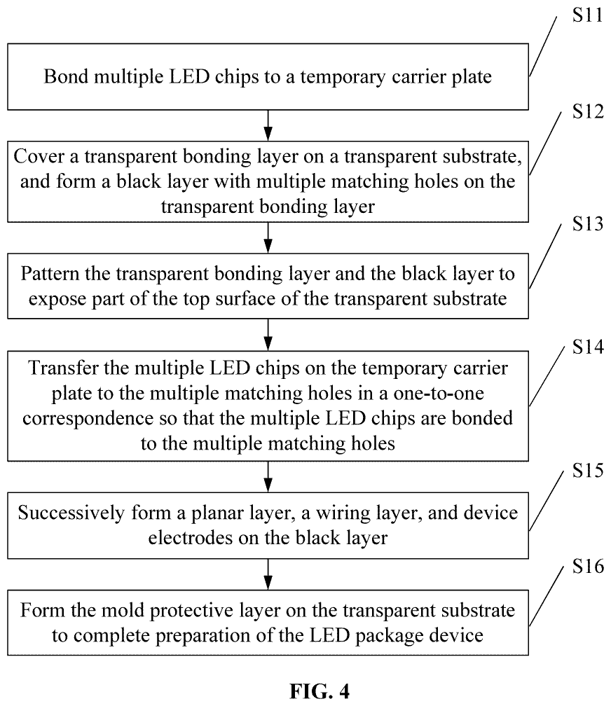

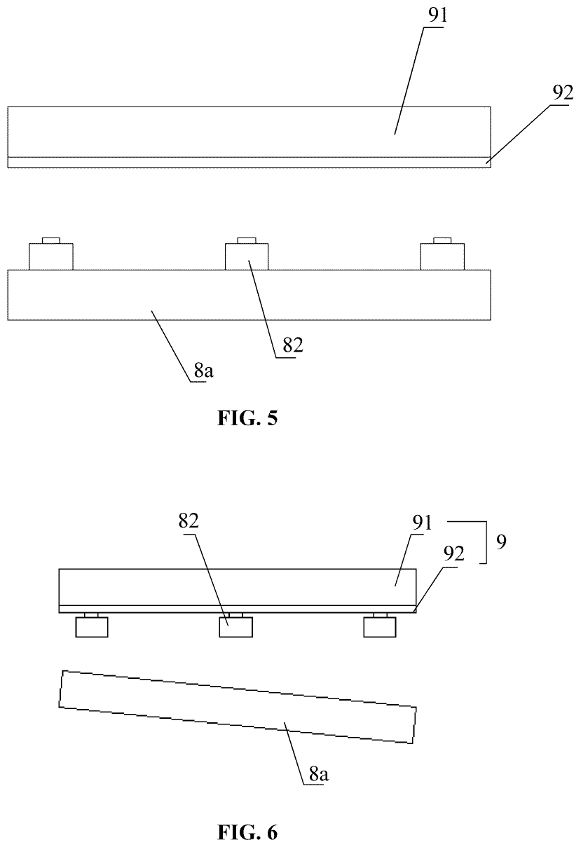

Specifically, as shown in FIG. 5, a temporary carrier plate 9 is formed by bonding an adhesive film to a temporary substrate 91. Multiple second chips 82 (chip on wafer (COW)) with a substrate 8a are bonded to the temporary carrier plate 9. The substrate 8a is lifted off through laser etching technology to obtain the temporary carrier plate 9 (chip on carrier (COC)) to which the LED chips are bonded.

Further, the temporary substrate 91 may be one of rigid materials such as glass, sapphire, or silicon wafer to facilitate carrying and transfer of LED chips.

Specifically, the adhesive film 92 may be a polydimethylsiloxane (PDMS) thin film. The PDMS thin film is one of organosilicon thin films and has a certain elasticity, and when the LED chips are bonded, the pressing force of the LED chips can be buffered to reduce the risk of damage to the LED chips.

Further, alternatively, the adhesive film 92 may be a UV film having viscosity. Specifically, when the temporary carrier plate 9 is bonded, the temporary carrier plate 9 may be lightly pressed so that the multiple second chips 82 are in full contact with the adhesive film 92 on the temporary carrier plate 9 to ensure that the multiple second chips 82 can be bonded to the temporary carrier plate 9.

Further, the first chip 81 and the third chip 83 are bonded to the temporary carrier plate through the same method. Details are not described here.

In S12, a transparent bonding layer 2 and a black layer 3 are covered on a transparent substrate 1. Multiple matching holes are formed on the black layer 3.

Specifically, the transparent bonding layer 2 may be formed on the transparent substrate 1 through a spin-coating method. Alternatively, the transparent bonding layer 2 may be formed through a vacuum attaching method. The transparent bonding layer 2 has a high viscosity and is well combined with the transparent substrate 1, the black layer 3, and the LED chips, thereby improving the structure reliability of the package device.

Further, the viscosity of the transparent bonding layer 2 is higher than that of the adhesive film 92, thereby facilitating the bonding and transfer of the LED chips. The transparent bonding layer 2 has a certain elasticity so that when the LED chips are transferred, the pressing force of the LED chips can be buffered, thereby reducing the risk of damage to the chips.

Further, the thickness of the transparent bonding layer 2 may be between 1 micron and 100 microns according to actual processing requirements.

Specifically, the black layer 3 is formed on the transparent bonding layer 2 through a spin-coating process. That is, the black photoresist falling on the transparent bonding layer 2 is spin-coated on the surface of the transparent bonding layer 2. Multiple matching holes are formed on the black layer 3 through exposure and development.

Specifically, the black photoresist is spin-coated on the transparent bonding layer 2 to form a black adhesive layer. That is, the black photoresist falling on the transparent bonding layer 2 is spin-coated on the surface of the transparent bonding layer 2. A pattern layer with hole-shaped light spots is formed by exposing the black adhesive layer. The hole-shaped light spots on the pattern layer are dissolved through a development process to form the black layer 3 with the multiple matching holes.

Further, in the exposure process of the photoresist, the photoresist in the exposure area is subjected to a chemical reaction. The photoresist is attenuated in black to form light spots. In the development process, the light spots and a developer react and dissolve to form the matching hole structure.

The multiple matching holes are configured to match with and mount the multiple LED chips 8. The multiple LED chips 8 are matched in the multiple matching holes and can be bonded to the transparent bonding layer 2 to ensure that the LED chips can emit light normally, and the light intensity and brightness of the device are improved.

In S13, the transparent bonding layer 2 and the black layer 3 are patterned.

Specifically, interlaced separation grooves 35 are formed on the black layer 3 and the transparent bonding layer 2 through a patterning process. The black layer 3 and the transparent bonding layer 2 are divided into multiple sub-units 34 based on the separation grooves 35. A first matching hole 31, a second matching hole 32, and a third matching hole 33 are disposed in any one of the multiple sub-units 34.

Further, the patterning manner is laser etching. The transparent bonding layer 2 and the black layer 3 are trimmed through the laser etching. The top surface of the transparent substrate 1 is exposed on the path of etching. Thus, the subsequent mold protective layer 7 can be combined with the transparent substrate 1, thereby avoiding the black layer 3 and the transparent bonding layer 2 from directly contacting the external environment, prolonging the path of water vapor invading the interior of the device, reducing the risk of water vapor invading, and prolonging the service life of the device.

Further, alternatively, the patterning manner may be chemical etching. The black layer 3 and the transparent bonding layer 2 are etched by coating a chemical reagent.

In S14, the multiple LED chips 8 on the temporary carrier plate 9 are bonded to the multiple matching holes in a one-to-one correspondence.

Specifically, the temporary carrier plate 9 is bonded to the transparent substrate 1. The second chip 82 is correspondingly bonded in the second matching hole 32. The bottom surface of the second chip 82 is in contact with the transparent bonding layer 2. Since the viscosity of the transparent bonding layer 2 is higher than that of the adhesive film 92, when the temporary carrier plate 9 is removed, the second chip 82 can be bonded to the transparent bonding layer 2 to complete the transfer of the second chip 82.

Further, the bottom surface of the second chip 82 is a light emission surface. The second chip 82 may emit light outwardly through the transparent substrate 1.

Further, the first chip 81 and the third chip 83 are transferred in the same manner. The preparation of the LED device is completed after three transfers.

Further, the viscosity of the black layer 3 to the LED chips is much less than that of the transparent bonding layer 2 to the LED chips. Alternatively, the black layer 3 is made of a completely non-bonding material. Thus, when the second chip 82 is in contact with the second matching hole 32, damage caused by the influence of the black layer 3 can be avoided.

Further, the first chip 81, the second chip 82, and the third chip 83 are transferred according to the order of heights of the chips from low to high. Since the height of a transferred chip is lower than the height of a to-be-transferred chip, the contact between the transferred chip and the temporary carrier plate 9 of the to-be-transferred chip can be avoided, thereby reducing the risk of damage to the chips.

In S15, a planar layer 4, a wiring layer 5, and device electrodes 6 are successively formed on the black layer 3.

Specifically, the planar layer 4 is prepared on the black layer 3. The planar layer 4 is made of an insulation material. The first chip 81, the second chip 82, and the third chip 83 are wrapped and covered. The edge of the planar layer 4 is flush with the edge of the black layer 3 through photolithographic pattern processing. Thus, the mold protective layer 7 can be directly contacted with the transparent substrate 1.

Further, opening portions are formed on the top of the planar layer 4 at positions corresponding to the multiple LED chips 8 through the photolithographic pattern processing. Top electrodes of the first chip 81, the second chip 82, and the third chip 83 may be exposed on the top surface of the planar layer 4.

Specifically, the wiring layer 5 is prepared above the planar layer 4 through an evaporation process. A conductive film material is placed on the planar layer 4. The wiring layer 5 is formed on the surface of the planar layer 4 through vacuum evaporation. The wiring layer 5 is electrically connected to the top electrodes of the first chip 81, the second chip 82, and the third chip 83.

Specifically, the device electrodes 6 are prepared on the wiring layer 5 through an electroplating process. The device electrodes 6 are configured to access an external circuit.

Further, the device electrodes 6 may be prepared on the wiring layer 5 through electroless plating. The electroless plating is a plating method by which metal ions in a plating solution are reduced to metal by relying on a suitable reductant without an applied current, and the metal is deposited on the surface of the wiring layer 5. The electroless plating has characteristics of simple process, energy saving and environmental protection, and the like.

In S16, the mold protective layer 7 is formed on the transparent substrate 1 to complete preparation of the LED package device.

Specifically, a black epoxy resin is poured on the transparent substrate 1 for molding to form the mold protective layer 7. The device electrodes 6 are exposed on the top of the mold protective layer 7 through mechanical grinding and polishing processes to facilitate access to an external circuit.

Further, the mold protective layer 7 and the transparent substrate 1 are directly contacted and bonded. The transparent bonding layer 2, the black layer 3, the planar layer 4, and the wiring layer 5 are completely wrapped in the mold protective layer 7. Thus, the path of water vapor invading the LED package device 10 is prolonged, the risk of water vapor invading is reduced, and the service life of the LED package device 10 is prolonged.

Specifically, the transparent substrate 1 is cut along the central axis of the separation groove 35. The transparent substrate 1 may be divided into multiple LED devices 10 having the same size.

This embodiment of the present disclosure provides a preparation method of an LED package device. According to the preparation method, the LED chips are transferred through the temporary carrier plate 9 during a preparation process to improve the preparation efficiency, and the mold protective layer 7 and the transparent substrate 1 are directly contacted and bonded through a patterning process, thereby prolonging the path of water vapor entering the LED device 10, improving the structure stability of the LED package device 10, and prolonging the service life of the device.

In addition, the preceding describes an LED package device and a preparation method thereof, and a display device provided in the embodiments of the present disclosure in detail. The principles and implementations of the present disclosure are described herein with specific examples. The preceding description of the embodiments is merely for assisting in understanding the method of the present disclosure and its core ideas. At the same time, for those skilled in the art, according to the idea of the present disclosure, there are changes in specific implementations and applications. In summary, the content of this specification should not be construed as limiting the present disclosure.

What is claimed is:

1. A light-emitting diode (LED) package device, comprising:
a transparent substrate, a black layer, a transparent bonding layer, a plurality of LED chips, and a mold protective layer, wherein
the plurality of LED chips are fixed to the transparent substrate based on the transparent bonding layer;
the black layer is configured to cover the transparent bonding layer, the black layer is provided with a plurality of matching holes, and the plurality of LED chips are matched in the plurality of matching holes in a one-to-one correspondence;
cover area of the transparent bonding layer is S1, area of a top surface of the transparent substrate is S2, and a constraint relationship between S1 and S2 is S1<S2; and
the mold protective layer is configured to wrap the black layer, the transparent bonding layer, and the plurality of LED chips on the transparent substrate.

2. The LED package device according to claim 1, wherein the transparent bonding layer is located in the top surface of the transparent substrate, and an outer contour edge of the transparent bonding layer is not in contact with a side of the transparent substrate.

3. The LED package device according to claim 1, further comprising:
a planar layer, wherein the planar layer is configured to cover a surface of the black layer, and a top surface of the planar layer is flush with top surfaces of the plurality of LED chips.

4. The LED package device according to claim 3, further comprising:
a wiring layer and device electrodes, wherein
the wiring layer is disposed on the planar layer, and electrically connected to top electrodes of the plurality of LED chips;
the device electrodes are located on the wiring layer and connected to the wiring layer;
the device electrodes comprise a plurality of sub-electrodes, and the plurality of sub-electrodes comprise at least one common electrode; and
cathode ends of the plurality of LED chips are connected to the at least one common electrode, or anode ends of the plurality of LED chips are connected to the at least one common electrode.

5. The LED package device according to claim 1, wherein the transparent bonding layer is made of an acrylic film, an epoxy resin film, a silicone resin film, a silica gel film, or an ultra-violet (UV) film.

6. The LED package device according to claim 1, wherein the black layer is made of black photoresist, or the black layer is a titanium aluminum nitride thin film.

7. The LED package device according to claim 1, wherein a thickness of the black layer is h1, and a value range of h1 is h1≤1 μm.

8. The LED package device according to claim 3, wherein the planar layer is an insulation material.

9. A preparation method of a light-emitting diode (LED) package device, applied to preparation of a LED package device, wherein the LED package device comprises a transparent substrate, a black layer, a transparent bonding layer, a plurality of LED chips, and a mold protective layer, wherein the plurality of LED chips are fixed to the transparent substrate based on the transparent bonding layer; the black layer is configured to cover the transparent bonding layer, the black layer is provided with a plurality of matching holes, and the plurality of LED chips are matched in the plurality of matching holes in a one-to-one correspondence; cover area of the transparent bonding layer is S1, area of a top surface of the transparent substrate is S2, and a constraint relationship between S1 and S2 is S1<S2; and the mold protective layer is configured to wrap the black layer, the transparent bonding layer, and the plurality of LED chips on the transparent substrate; and
wherein the method comprises:
bonding the plurality of LED chips to a temporary carrier plate;
covering the transparent bonding layer on the transparent substrate, and forming the black layer with the plurality of matching holes on the transparent bonding layer;
patterning the transparent bonding layer and the black layer to expose part of a top surface of the transparent substrate;
transferring the plurality of LED chips on the temporary carrier plate to the plurality of matching holes in the one-to-one correspondence so that the plurality of LED chips are bonded to the transparent bonding layer exposed in the plurality of matching holes;
successively forming a planar layer, a wiring layer, and device electrodes on the black layer; and
forming the mold protective layer on the transparent substrate to complete the preparation of the LED package device.

10. The preparation method of an LED package device according to claim 9, wherein bonding the plurality of LED chips to the temporary carrier plate comprises:
attaching an adhesive film on a temporary substrate to form the temporary carrier plate, and attaching the plurality of LED chips with a substrate on the temporary carrier plate; and
lifting the substrate off through laser etching technology to obtain the temporary carrier plate to which the plurality of LED chips are bonded.

11. The preparation method of an LED package device according to claim 10, wherein the temporary substrate is made of glass, sapphire, or silicon.

12. The preparation method of an LED package device according to claim 10, wherein the adhesive film is a polydimethylsiloxane (PDMS) film or an ultra-violet (UV) film.

13. The preparation method of an LED package device according to claim 9, wherein covering the transparent bonding layer on the transparent substrate comprises:
forming the transparent bonding layer on the transparent substrate through a spin-coating method, or forming the transparent bonding layer through a vacuum attaching method.

14. The preparation method of an LED package device according to claim 9, wherein forming the black layer with the plurality of matching holes on the transparent bonding layer comprises:
spin-coating black photoresist on the transparent bonding layer to form a black adhesive layer;
exposing the black adhesive layer to form a pattern layer with hole-shaped light spots; and
dissolving the hole-shaped light spots on the pattern layer through a development process to form the black layer with the plurality of matching holes.

15. The preparation method of an LED package device according to claim 9, wherein the patterning is laser etching or chemical etching.

16. The preparation method of an LED package device according to claim 9, wherein transferring the plurality of LED chips on the temporary carrier plate to the plurality of matching holes in the one-to-one correspondence so that the plurality of LED chips are bonded to the transparent bonding layer exposed in the plurality of matching holes comprises:
bonding the plurality of LED chips to the plurality of matching holes according to an order of heights of the plurality of LED chips from low to high in the one-to-one correspondence.

17. The preparation method of an LED package device according to claim 9, wherein forming the planar layer on the black layer comprises:
processing the planar layer through photolithography to enable an edge of the planar layer to be flush with the black layer; and
forming opening portions at corresponding positions of the plurality of LED chips through a photolithography process.

18. The preparation method of an LED package device according to claim 9, wherein successively forming the wiring layer and the device electrodes on the black layer comprises:
preparing the wiring layer above the planar layer through evaporation; and
preparing the device electrodes on the wiring layer through an electroplating process or through an electroless plating process.

19. The preparation method of an LED package device according to claim 9, wherein forming the mold protective layer on the transparent substrate comprises:
pouring an epoxy resin on the transparent substrate for molding to form the mold protective layer, and exposing the device electrodes on a top of the mold protective layer through grinding and polishing processes.

20. A display device, comprising:
a carrier plate and a plurality of display modules arrayed on the carrier plate, wherein
a display module of the plurality of display modules comprises a circuit board, wherein the circuit board is provided with a plurality of LED package devices, wherein a LED package device of the plurality of LED package devices comprises a transparent substrate, a black layer, a transparent bonding layer, a plurality of LED chips, and a mold protective layer, wherein the plurality of LED chips are fixed to the transparent substrate based on the transparent bonding layer; the black layer is configured to cover the transparent bonding layer, the black layer is provided with a plurality of matching holes, and the plurality of LED chips are matched in the plurality of matching holes in a one-to-one correspondence; cover area of the transparent bonding layer is S1, area of a top surface of the transparent substrate is S2, and a constraint relationship between S1 and S2 is S1<S2; and the mold protective layer is configured to wrap the black layer, the transparent bonding layer, and the plurality of LED chips on the transparent substrate.
